(19) United States
(12) Patent Application Publication
(10) Pub. No.: US 2013/0236837 A1
(43) Pub. Date: Sep. 12, 2013

(54) METHOD FOR FORMING A RESIST PATTERN AND A METHOD FOR PROCESSING A SUBSTRATE UTILIZING THE METHOD FOR FORMING A RESIST PATTERN

(71) Applicant: FUJIFILM CORPORATION, Tokyo (JP)

(72) Inventors: Soichiro HONDA, Shizuoka-ken (JP); Tadashi OMATSU, Shizuoka-ken (JP); Hideaki TSUBAKI, Shizuoka-ken (JP)

(73) Assignee: FUJIFILM Corporation, Tokyo (JP)

(21) Appl. No.: 13/852,641

(22) Filed: Mar. 28, 2013

Related U.S. Application Data
(63) Continuation of application No. PCT/JP2011/005450, filed on Sep. 28, 2011.

(30) Foreign Application Priority Data
Sep. 29, 2010 (JP) 2010-218748

(51) Int. Cl. G03F 7/20; G03F 7/26

(52) U.S. Cl. CPC G03F 7/20; G03F 7/26
USPC 430/323; 430/325

(57) ABSTRACT

Collapse of resist patterns in the formation of resist patterns that employ chemically amplified resist material is suppressed. A method for forming a resist pattern includes the steps of: coating a substrate with a chemically amplified resist material; exposing the resist material; and developing the exposed resist material, to form a resist pattern having an aspect ratio AR of 1.5 or greater in a resist film formed by the resist material. A close contact process that improves close contact properties between the substrate and the resist film is controlled such that the thickness of residual film of the resist film is greater than or equal to 1 nm and less than or equal to 1.83·AR+1.73 nm.

### TECHNICAL FIELD

The present invention is related to a method for forming a resist pattern during the production of a magnetic transfer master disk, a nanoimprinting molds, and the like. The present invention is also related to a method for processing a substrate that utilizes the method for forming a resist pattern.

### BACKGROUND ART

Recently, magnetic transfer methods and nanoimprinting methods that efficiently transfer two dimensional and three dimensional patterns have been developed.

Magnetic transfer is a transfer technique which is performed during the production of magnetic recording media. In magnetic transfer, a magnetic transfer master disc having a fine magnetic pattern on the surface thereof is placed in close contact with a slave medium also referred to as a transfer target medium). A transfer magnetic field is applied in this state, and information corresponding to the magnetic pattern (servo signals, for example) is transferred onto the slave medium. Meanwhile, nanoimprinting is a transfer technique which is performed during the production of DTM (Discrete Track Media) and RPM (Bit Patterned Media). In nanoimprinting, a nanoimprinting master carrier having a fine pattern of protrusions and recesses is pressed against thermoplastic resin, photocuring resin, or the like, to transfer the pattern of protrusions and recesses onto the resin.

Generally, the aforementioned master mold (including the master disk and the master carrier is formed by electroforming employing a glass plate, a Si wafer, etc., having a pattern corresponding to the pattern of the master mold as an original plate, and causing a metal material to precipitate on the original disk. Accordingly, miniaturization of the pitch of the pattern of original plates is desired, in order to produce master molds capable of keeping pace with the miniaturization of pitch accompanying improvements in recording density. Particularly, patterns having pitches of 60 nm or less are desired for the production of the aforementioned next generation recording media.

However, when resist film is formed on a substrate which is a base for an original plate, a predetermined pattern is drawn by electron beam lithography, and the pattern is developed, a problem of resist patterns collapsing has arisen due to an increase in capillary force due to the miniaturization of the pitch of the pattern and a decrease in the contact area between the resist film and the substrate.

Therefore, improvements are desired in resist pattern forming techniques, and improvements in the close contact properties between substrates and resist films has become a necessary objective. As disclosed in Japanese Unexamined Patent Publication No. 7(1995)-092694 and Japanese Unexamined Patent Publication No. 8(1996)-076352, commonly, methylation or hydrophobization is administered by HMDS (hexamethyldisilazane: (CH₃)₃SiNHSi(CH₃)₃) onto Si wafers in order to improve close contact properties with resist.

Alternatively, as disclosed in Japanese Unexamined Patent Publication No. 9 (1997)-054440, a silane coupling agent is employed to form an extremely thin organic molecule layer on a surface on which a resist film is formed by the LB (Langmuir Blodgett) method, etc. The method of Japanese Unexamined Patent Publication No. 9 (1997)-054440 chemically modifies the surface of a substrate with organic molecules having functional groups having great bonding force with the substrate, to improve the close contact properties between the substrate and the resist film.

### DISCLOSURE OF THE INVENTION

However, in the close contact process that employs HMDS as a close contact processing agent, presently the close contact forces are insufficient with respect to the miniaturization of patterns in recent years. The aforementioned problem of patterns collapsing arises significantly during formation of patterns having aspect ratios of 1.5 or greater. Meanwhile, the use of silane coupling agents as close contact processing agents as disclosed in Japanese Unexamined Patent Publication No. 9(1997)-054440 improves close contact properties to a certain degree, but there are still cases in which patterns collapse. This is because processing fluids, such as developing fluid and cleansing fluids, enter gaps between substrates and resist films, to reduce the effects of close contact processes.

In addition, if miniaturization of pattern pitches progresses further, the contact areas between substrates and the protrusions of resist patterns will decrease. Therefore, there is a limit to the degree to which collapsing of patterns can be suppressed from a viewpoint of improving the close contact properties between a substrate and a resist film.

The present invention has been developed in view of the foregoing circumstances. It is an object of the present invention to provide a method fro forming a resist pattern that employs a chemically amplified resist material that enables collapsing of resist patterns to be suppressed.

In addition, it is another object of the present invention to provide a method for processing substrates that can process substrates with high precision and high yields.

A method for forming a resist pattern of the present invention that achieves the above objective comprises the steps of:
coating a substrate with a chemically amplified resist material;
exposing the resist material; and
developing the exposed resist material, to form a resist pattern having an aspect ratio AR of 1.5 or greater in a resist film formed by the resist material; wherein:
a close contact process that improves close contact properties between the substrate and the resist film is controlled such that the thickness of residual film of the resist film is greater than or equal to inn and less than or equal to 1.83·AR+1.73 nm.

In the present specification, a resist pattern having “an aspect ratio of 1.5 or greater” refers to a resist pattern in which the ratio of the width and the thickness of the resist film at portions where the resist material remains (protrusions of the pattern) is 1.5 or greater. It is sufficient for the resist pattern to include a portion at which the ratio is 1.5 or greater.

It is preferable for the method for forming a resist pattern of the present invention to adopt a configuration, wherein:
an amino series silane coupling agent having an amino group is employed as a close contact processing agent in the close contact process; and
the close contact process is executed by coating the substrate with a diluted solution of the amino series silane coupling agent.

It is preferable for the concentration of the amino series silane coupling agent within the diluted solution to be controlled to control the close contact process.

It is preferable for the thickness of residual film to be within a range from 1 nm to 4 nm.

A method for processing a substrate of the present invention comprises:

forming a resist film having a predetermined resist pattern on a substrate by the aforementioned method for forming a resist pattern;

removing the residual film of the resist film; and

etching the substrate using the resist film as a mask, to form a pattern of protrusions and recesses corresponding to the resist pattern on the substrate.

The method for forming a resist pattern of the present invention coats a chemically amplified resist material on a substrate, then exposes and develops the resist material, to form a resist pattern on a resist film formed by the resist material having an aspect ratio of 1.5 or greater. A close contact process that improves close contact properties between the substrate and the resist film is controlled such that the thickness of residual film of the resist film is greater than or equal to 1 nm and less than or equal to 1.83·AR+1.73 nm. Therefore, the presence of residual film, which is designed to be thicker than residual film of conventional resist patterns will suppress entry of processing fluids such as developing fluid between the substrate and the resist film. Further, the residual film which is designed to be thicker will also function as support for protrusions of the resist pattern. As a result, it becomes possible to suppress collapsing of a resist pattern in a method for forming a resist pattern employing a chemically amplified resist material.

Further, the method for processing a substrate of the present invention performs dry etching using the resist film formed by the above method for forming a resist pattern, in which collapsing of the resist pattern is suppressed, as a mask. Therefore, substrates can be processed highly precisely and with favorable yields.

### BRIEF DESCRIPTION OF THE DRAWINGS

FIG. 1 is a schematic sectional diagram that illustrates a resist film having a predetermined thickness, formed on a substrate by a method for forming a resist pattern of the present invention.

FIG. 2A is a schematic sectional diagram that illustrates the state of a close contact interface between a substrate and a resist film which are placed in close contact by a silane coupling agent.

FIG. 2B is a schematic sectional diagram that illustrates the state of a close contact interface between a substrate and a resist film which are placed in close contact by HMDS.

FIG. 3 is a graph in which lower limit values and upper limit values of ranges of the thickness of residual film are plotted, based on Table 5.

### BEST MODE FOR CARRYING OUT THE INVENTION

Hereinafter, an embodiment of the present invention will be described with reference to the attached drawings. However, the present invention is not limited to the embodiments to be described below. Note that the dimensional scale ratios, etc. of the constituent elements within the drawings are not necessarily as the actual scale ratios in order to facilitate visual understanding.

### [Method for Forming a Resist Pattern]

A method for forming a resist pattern according to the present embodiment prepares a diluted solution that includes a close contact processing agent of which the concentration is controlled such that the thickness of a residual film 3 of a resist film 2 is greater than or equal to 1 nm and less than or equal to 1.83·AR+1.73 nm. A close contact process is executed by coating the diluted solution onto a substrate 1. The resist film 2 is formed on the surface of the substrate on which the close contact process has been administered by coating a chemically amplified resist material thereon. The resist film 2 is exposed by electron beam lithography according to a predetermined resist pattern having an aspect ratio AR of 1.5 or greater. Then, the resist film 2 is developed by a developing liquid.

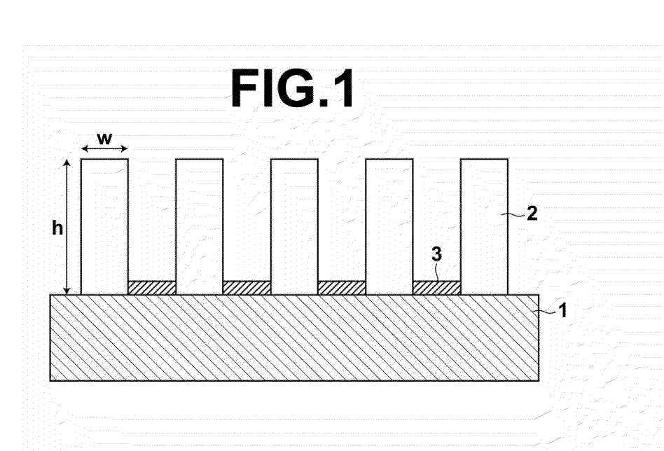

In the present invention, significant advantageous effects are obtained compared to conventional method if the aspect ratio AR of the resist pattern is 1.5 or greater. Accordingly, in the present invention, it is preferable for the aspect ratio AR of the resist pattern to be 1.5 or greater, more preferably 1.5 or greater and 4.0 or less, and most preferably 1.5 or greater and 3.0 or less. As illustrated in FIG. 1, the aspect ratio AR is a ratio of the width w and the thickness h of the resist film at portions where the resist material remains (protrusions of the pattern). Commonly, the problem of resist patterns collapsing becomes more likely to occur as the aspect ratio AR becomes greater.

The method for producing a resist pattern of the present invention controls the close contact process such that the thickness of the residual film 3 of the resist film 2 is 1 nm or greater and 1.83·AB+1.73 nm or less. This is because the effect of suppressing collapsing of patterns is weakened if the thickness of the residual film 3 is less than 1 nm, and the pattern formability of a substrate after a substrate processing step by etching deteriorates if the thickness of the residual film 3 is greater than 1.83·AR+1.73 nm.

The residual film 3 refers to a portion of the resist film 2 that remains at the bottoms of recesses of the resist pattern that could not be removed by the developing step. In the present invention, the thickness of the residual film 3 is designed to be thicker than conventional residual films. The specific range of the thickness of the residual film 3 that enables the advantageous effects of the present invention to be obtained is determined according to the aspect ratio AR of the resist pattern. That is, the thickness of the resist film 3 of the present invention is determined taking a desired thickness h of the resist film and a desired width w of the protrusions of the resist pattern into consideration as a whole.

The close contact process can be controlled by selecting the material of the close contact processing agent, the concentration of the close contact processing agent within the solution, and by controlling other processing conditions.

The material of the close contact processing agent is not particularly limited, but amino series silane coupling agents are preferable from the viewpoint of bonding properties with the substrate and bonding properties with the resist material. Various known amino series silane coupling agents may be utilized. Specific examples include: 3-triethoxysilyl-N-(1,3-dimethyl-butyridene) propyl amine (KBE9103 by Shin-Etsu Chemical Co., Ltd.); N-phenyl-γ-aminopropyl trimethoxysilane (KBM573 by Shin-Etsu Chemical Co., Ltd.); N-2-(aminoethyl)-3-aminopropyl methyl dimethoxysilane (KBM602 by Shin-Etsu Chemical Co., Ltd.); γ-aminopropyl trimethoxysilane (KBM903 by Shin-Etsu Chemical Co., Ltd.); 3-2-aminoethyl) aminopropyl trimethoxysilane (Z6094 by Dow Corning Toray Co., Ltd.); and aminoethyl aminopropyl trimethoxysilane (Z6026 by Toray/Dow Corning K. K.).

The solvent in which the close contact processing agent is diluted is not particularly limited, and PGME (Propylene Glycol Monomethyl Ether) or PGMEA (Propylene Glycol Monomethyl Ether Acetate) may be utilized.

The substrate is an object to be processed by the method for processing a substrate of the present invention. The substrate is formed by Si, Cr, C, Sn, Mo, Hf, or oxides thereof.

The close contact process is executed by coating the substrate with the close contact processing agent by the spin coat method and the immersion method, etc., then drying the substrate by applying heat. Here, in order to form a residual film having a certain thickness, a close contact processing layer (a layer which is formed on the surface of the substrate by the close contact process) of the present invention has a certain thickness. It is preferable for the thickness of the close contact processing layer to be within a range from 1 nm to 6 nm, and more preferably within a range from 1 nm to 2 nm.

The resist material is not particularly limited, but it is preferable for the resist material to be a chemically amplified resist material which is capable of becoming highly sensitive. A chemically amplified resist material is a polymer in which a photo acid generating agent is mixed, which functions as a positive type resist or a negative type resist by the polymer undergoing elimination reactions, hydrolysis reactions, or cross linking reactions among polymer molecules occurring as chain reactions by irradiation of far ultraviolet light. Examples of the photo acid generating agent include: diaryliodonium salt, triarylsulfonium salt, and derivatives thereof. Note that a negative type chemically amplified resist material is constituted by a mixture of a resin and an acid generating agent or a mixture of a resin, an acid generating agent, and a cross linking agent. Meanwhile, a positive type chemically amplified resist material is that in which a dissolution inhibiting agent is mixed instead of the cross linking agent in the negative type chemically amplified resist material.

Exposure and development are not particularly limited, and known techniques may be employed for these steps.

Hereinafter, the operational effects of the present invention will be described.

The present invention controls the close contact process such that the thickness of the residual film of the resist film is greater than or equal to 1 nm and less than or equal to 1.83·AR+1.73 nm. Accordingly, entry of processing fluids such as developing fluid between the substrate and the resist film can be suppressed during the developing step, etc. Further, such a residual film also functions as support for the protrusions of the resist pattern in the horizontal direction. As a result, the presence of the residual film having the predetermined thickness can suppress collapsing of the protrusions of the pattern having a high aspect ratio, that is, protrusions having decreased contact area with the substrate and are likely to be influenced by capillary force of the processing fluids.

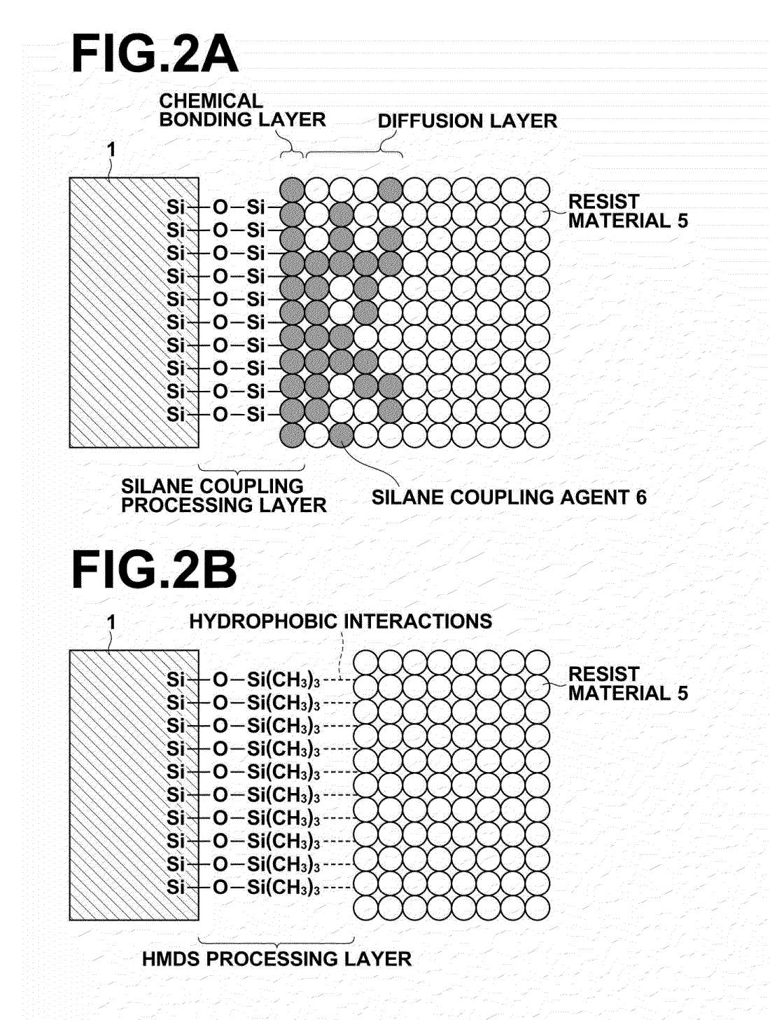

The reason why controlling the close contact process enables the thickness of the residual film to be controlled is believed to be as follows. For example, in the case that a silane coupling agent is employed as the close contact processing agent as in the present embodiment, it is thought that the substrate 1 and the resist film are in a close contact state as illustrated in FIG. 2A. FIG. 2A is a schematic diagram that illustrates the manner in which a silane coupling agent 6 provided on the substrate 1 forms a chemical bonding layer that bonds with the resist material 5, and a portion of the silane coupling agent 6 diffuses into the resist film to form complex bonds therein to cause the resist film to closely contact the substrate 1. First, a silane coupling processing layer is formed on the substrate 1 by the silane coupling agent 6 being coated thereon. Thereafter, the resist material 5 is coated on the silane coupling processing layer, and functional groups in the vicinity of the surface of the silane coupling processing layer chemically bond with the resist material, to form the chemical bonding layer. In the present invention, the silane coupling processing layer is set to have a certain degree of thickness, and therefore a portion of the silane coupling agent 6 does not contribute to formation of the chemical bonding layer. The portion of the silane coupling agent 6 that does not contribute to the formation of the chemical bonding layer is incorporated into the resist film while aggressively diffusing through the resist film and forming complex bonds therewith due to its compatibility, and is cured with the resist material 5. It is considered that the residual film having the predetermined thickness is formed corresponding to the thickness of the region within the resist film in which the silane coupling agent 6 has diffused (diffused layer) in the present invention.

In contrast, in a close contact process that utilizes conventional HMDS, an HMDS processing layer is formed as a close contact processing layer as illustrated in FIG. 2B. However, the bonds between HMDS and the resist material are physical bonds caused by hydrophobic interactions. Therefore, the bonding force is weaker than a case in which the silane coupling agent is employed. In addition, HMDS does not have compatibility, and therefore will not aggressively diffuse into the resist film. In addition, even if an extremely thin organic molecule layer is formed as a close contact processing layer as disclosed in Japanese Unexamined Patent Publication No. 9 (1997)-054440, control of the thickness of residual film cannot be exerted even if the close contact properties can be improved by a chemical bonding layer formed thereby.

Conventionally, it had been considered that it would be ideal for residual film to not be present at all. If residual is present, the accuracy of a resist pattern will deteriorate for the region at which the residual film is present, and further because a removal step for removing the residual film will become necessary. However, the present invention is based on a novel technical concept that overturns this conventional theory. That is, the intentionally leaves the residual film, which had been heretofore considered unnecessary, and controls the thickness thereof to have a certain thickness, to suppress collapsing of a resist pattern. As a result, it becomes possible to form fine patterns that satisfy the recent demand for miniaturization.

As described above, the method for forming a resist pattern of the present invention coats a chemically amplified resist material on a substrate, then exposes and develops the resist material, to form a resist pattern on a resist film formed by the resist material having an aspect ratio of 1.5 or greater. A close contact process that improves close contact properties between the substrate and the resist film is controlled such that the thickness of residual film of the resist film is greater than or equal to 1 nm and less than or equal to 1.83·AR+1.73 nm. Therefore, the presence of residual film, which is designed to be thicker than residual film of conventional resist patterns will suppress entry of processing fluids such as developing fluid between the substrate and the resist film. Further, the residual film which is designed to be thicker will also function as support for protrusions of the resist pattern. As a result, it becomes possible to suppress collapsing of a resist pattern in a method for forming a resist pattern employing a chemically amplified resist material.

### [Method for Processing a Substrate]

Next, an embodiment of the method for processing a substrate of the present invention will be described. The present embodiment processes a substrate using the method for forming the resist pattern described above.

First, a resist film having a predetermined pattern formed thereon is formed on a substrate employing the method for forming the resist pattern of the present invention described above. Next, residual film is removed, and dry etching is performed using the resist film on which the pattern has been formed as a mask, to form a pattern of protrusions and recesses corresponding to a pattern of protrusions and recesses formed on the resist film, to obtain a substrate having a predetermined pattern.

Meanwhile, in the case that the substrate is of a laminated structure and includes a metal layer on the surface thereof, dry etching is performed using the resist film as a mask, to form a pattern of protrusions and recesses in the metal layer corresponding to the pattern of protrusions and recesses formed in the resist film. Dry etching is further administered onto the substrate using the metal layer as a etching stop layer, to form a pattern of protrusions and recesses in the substrate, thereby obtaining a substrate having a predetermined pattern.

The residual film is removed by executing an oxygen plasma process (an ashing process).

The dry etching method is not particularly limited as long as it is capable of forming a pattern of protrusions and recesses in the substrate, and may be selected according to intended use. Examples of dry etching methods include: ion milling; RIE (Reactive Ion Etching); and sputter etching. Among these methods, the ion milling method and RIE (Reactive Ion Etching) are preferred.

The ion milling method is also referred to as ion beam etching. In the ion milling method, an inert gas such as Ar is introduced into an ion source, to generate ions. The generated ions are accelerated through a grid and caused to collide with a sample substrate to perform etching. Examples of ion sources include: Kauffman type ion sources; high frequency ion sources; electron bombardment ion sources; duoplasmatron ion sources; Freeman ion sources; and ECR (Electron Cyclotron Resonance) ion sources.

Ar gas may be employed as a processing gas during ion beam etching. Fluorine series gases or chlorine series gases may be employed as etchants during RIE.

As described above, the method for processing substrates of the present invention performs dry etching using the resist film, in which collapsing of a resist pattern is suppressed by the method for forming a resist film described above. Therefore, substrates can be processed with high accuracy and favorable yields.

### EXAMPLES

Examples of the method for forming a resist pattern of the present invention will be described below.

### Example 1

### Evaluation of Dependency on Materials of Pattern Collapse Suppressing Effect

Resist compositions were produced by combining the resins (groups A through C), the acid generating agents (PA group) and basic organic materials (AM group) as cross linking agents. The resist compositions that were produced and the combinations were as shown in Table 1. Whether the close contact processing agents indicated below exhibited pattern collapse suppressing effects with respect to each of the produced resist compositions was evaluated.

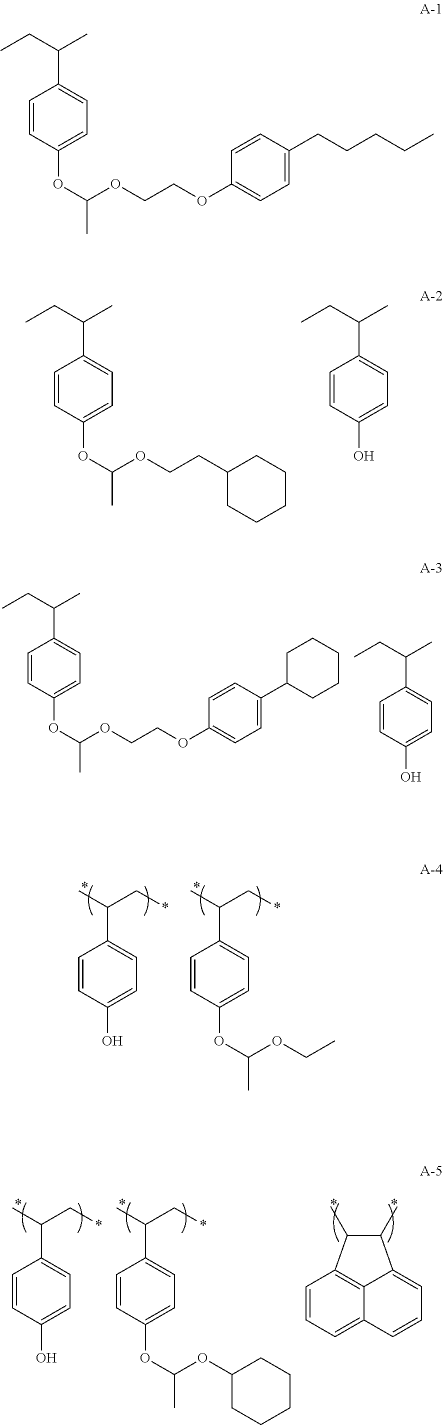

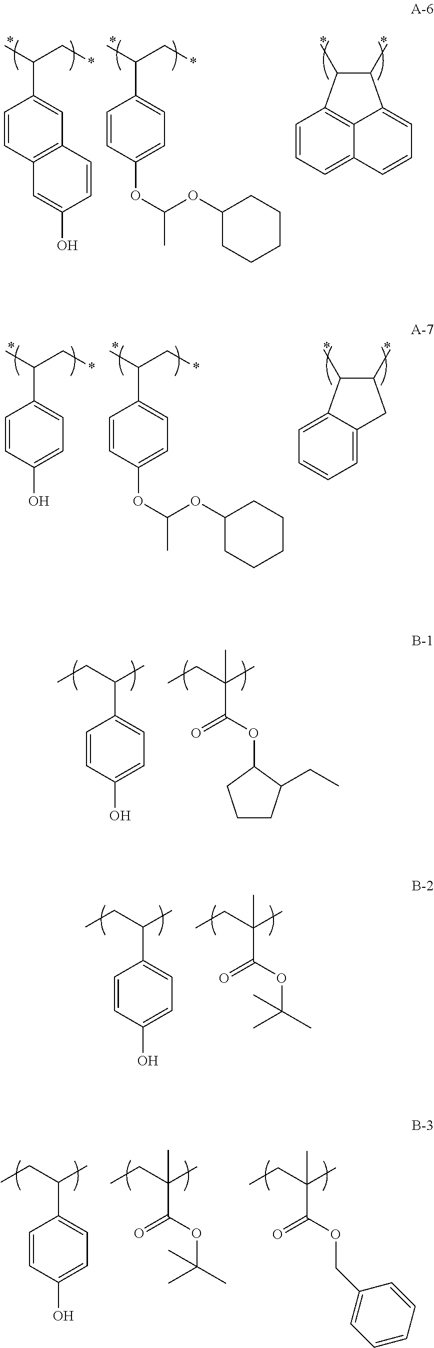

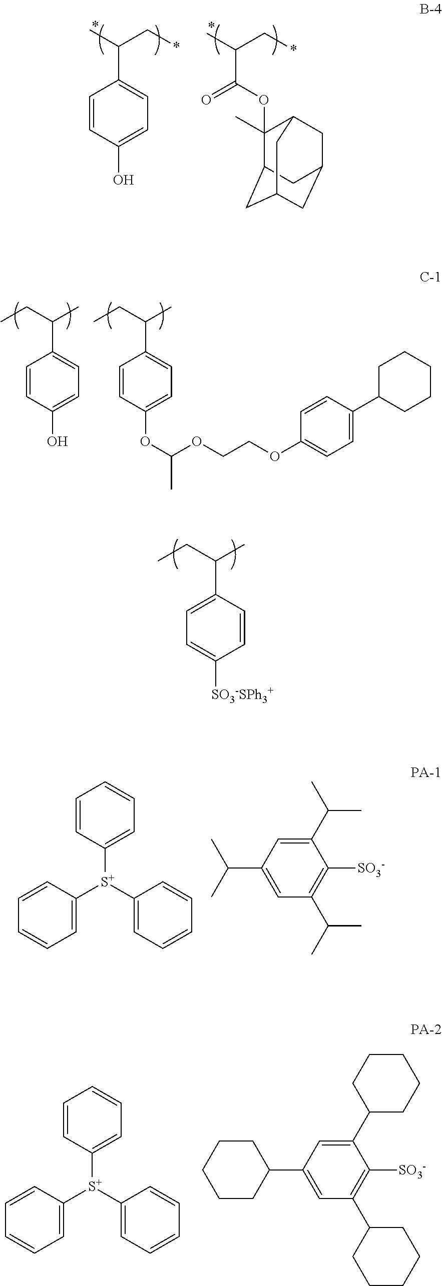

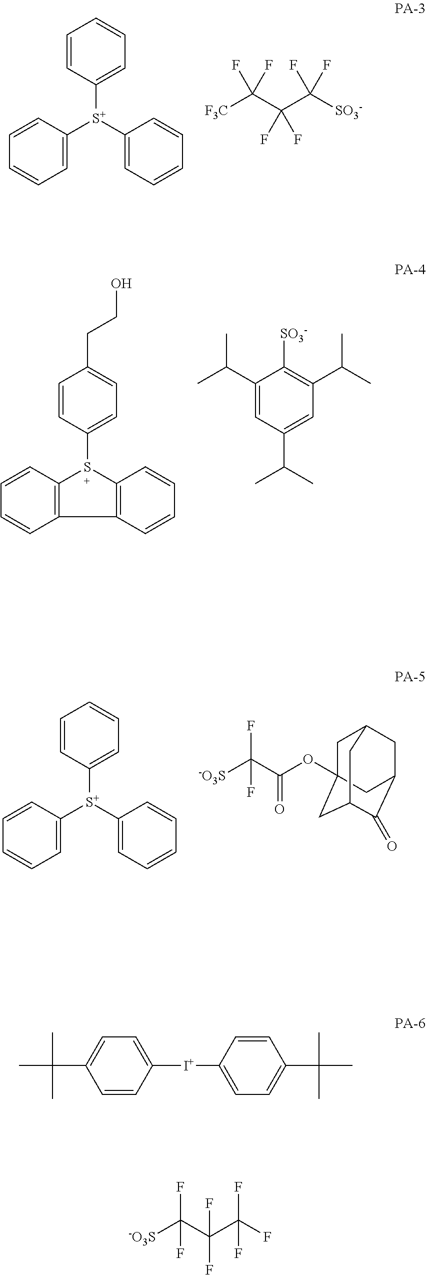

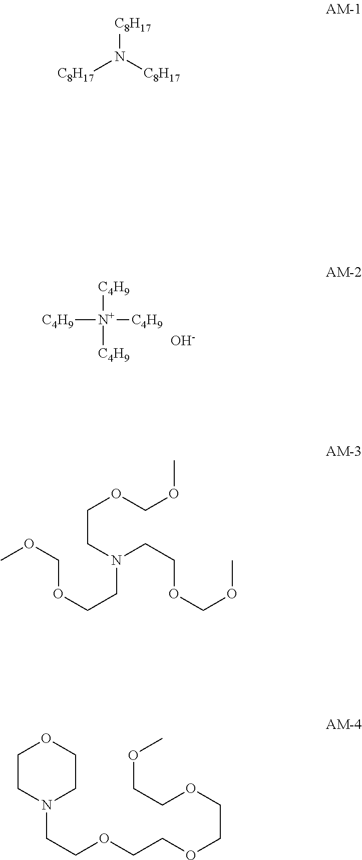

TABLE 1

| | | Acid | Organic Salt |
|---|---|---|---|
| | | Generating | Group |
| Resist Composition | Resin | Agent | Compound |
| 1 | A-1 | PA-1 | AM-2 |
| 2 | A-2 | PA-1 | AM-2 |
| 3 | A-3 | PA-1 | AM-2 |
| 4 | A-4 | PA-1 | AM-2 |
| 5 | A-5 | PA-1 | AM-2 |
| 6 | A-6 | PA-1 | AM-2 |
| 7 | A-7 | PA-1 | AM-2 |
| 8 | A-1 | PA-2 | AM-2 |
| 9 | A-2 | PA-2 | AM-2 |
| 10 | A-3 | PA-2 | AM-2 |
| 11 | A-1 | PA-3 | AM-2 |
| 12 | A-2 | PA-3 | AM-2 |
| 13 | A-3 | PA-3 | AM-2 |
| 14 | A-1 | PA-4 | AM-2 |
| 15 | A-2 | PA-4 | AM-2 |
| 16 | A-3 | PA-4 | AM-2 |
| 17 | A-1 | PA-5 | AM-2 |
| 18 | A-2 | PA-5 | AM-2 |
| 19 | A-3 | PA-5 | AM-2 |
| 20 | A-1 | PA-6 | AM-2 |
| 21 | A-2 | PA-6 | AM-2 |
| 22 | A-3 | PA-6 | AM-2 |
| 23 | A-1 | PA-1 | AM-1 |
| 24 | A-2 | PA-1 | AM-1 |
| 25 | A-3 | PA-1 | AM-1 |
| 26 | A-1 | PA-1 | AM-3 |
| 27 | A-2 | PA-1 | AM-3 |
| 28 | A-3 | PA-1 | AM-3 |
| 29 | A-1 | PA-1 | AM-4 |
| 30 | A-2 | PA-1 | AM-4 |
| 31 | A-3 | PA-1 | AM-4 |
| 32 | B-1 | PA-1 | AM-2 |
| 33 | B-2 | PA-1 | AM-2 |
| 34 | B-3 | PA-1 | AM-2 |
| 35 | B-4 | PA-1 | AM-2 |
| 36 | C-1 | | AM-1 |
| 37 | C-1 | | AM-2 |
| 38 | C-1 | | AM-3 |
| 39 | C-1 | | AM-4 |

3-triethoxysylil-N-(1,3-dimethylbutyridene) propylamine (KBE9103 by Shin-Etsu Chemical Co., Ltd.), 3-(2-aminoethyl) aminopropyl trimethoxysilane (Z6094 by Dow Corning Toray Co., Ltd.), aminoethyl aminopropyl trimethoxysilane (Z6026 by Dow Corning Toray Co., Ltd.), N-phenyl-γ-aminopropyl trimethoxysilane (KBM573 by Shin-Etsu Chemical Co., Ltd.), 3-isocyanatepropyl triethoxysilane (KBE 9007 by Shin-Etsu Chemical Co., Ltd.), 3-glycidoxypropyl trimethoxysilane (KEM403 by Shin-Etsu Chemical Co., Ltd.), 3-ureidopropyl trimethoxysilane (KBE585 by Shin-Etsu Chemical Co., Ltd.), and 3-mercaptopropyl trimethoxy silane (KBM803 by Shin-Etsu Chemical Co., Ltd.) were utilized as close contact processing agents. HMDS (by FUJIFILM Electronic Materials, Co., Ltd.) was utilized as a close contact processing agent for a reference sample.

Evaluations regarding whether a pattern collapse suppressing effect was present were performed in the following manner.

### Example 1-1

First, KBE9103 was employed as the close contact processing agent, and a diluted solution was prepared by diluting the KBE9103 to a concentration of 0.1 wt % in PGME. A close contact process was administered on a surface of a Si substrate having a (50 nm) thermally oxidized film thereon using the diluted solution. The close contact process was executed by coating the thermally oxidized film with the diluted solution by the spin coat method, then washing the thermally oxidized film by spin coating PGME thereon, and then heating the Si substrate at 120° C. for 15 minutes.

Next, each of the resist compositions shown in Table 1 was utilized to produce line and space type resist patterns having 40 lines having the aspect ratios shown in Table 2. The aspect ratio of each resist pattern was set by preparing three types of resist films, a first having a resist film thickness h of 40 nm (pitch: 60 nm), a second having a resist film thickness h of 60 nm (pitch: 70 nm), and a third having a resist film thickness h of 80 nm (pitch: 80 nm). An XY-EB lithography apparatus (JBX-6000FS/E by JEOL Ltd.,) was employed to perform exposure.

TABLE 2

| | Resist Film | Resist Film | Resist Film |
|---|---|---|---|
| | Thickness 40 nm | Thickness 60 nm | Thickness 80 nm |
| AR | Line Width (nm) | Line Width (nm) | Line Width (nm) |
| 1 | 40 | — | — |
| 1.2 | 33 | | |
| 1.5 | 27 | | |
| 1.6 | 25 | 38 | |
| 1.8 | — | 33 | |
| 2 | | 30 | 40 |
| 2.2 | | 27 | 36 |
| 2.4 | | — | 33 |
| 2.6 | | | 31 |
| 3 | | | 27 |
| 3.3 | | | 24 |

Evaluations regarding whether pattern collapse suppressing effects were present were rendered as follows. The resist patterns were observed with a scanning electron microscope capable of measuring the lengths of the resist patterns. In the case that no pattern collapses were found with respect to all of the resist compositions of Table 1, it was judged that the effect was exhibited, and an evaluation of “∘ (Good)” was rendered. In the case that a collapse in the pattern was found in at least one location of the resist patterns with respect to all of the resist compositions of Table 1, it was judged that the effect was not exhibited, and an evaluation of “x (Poor)” was rendered. In the case that the aspect ratio became greater, at what value pattern collapse began to occur was also evaluated.

### Example 1-2

The same evaluations as those for Example 1-1 were conducted, except that Z6094 was employed as the close contact processing agent.

### Example 1-3

The same evaluations as those for Example 1-1 were conducted, except that Z6026 was employed as the close contact processing agent.

### Example 1-4

The same evaluations as those for Example 1-1 were conducted, except that KBM573 was employed as the close contact processing agent.

### Example 1-5

The same evaluations as those for Example 1-1 were conducted, except that KBE9007 was employed as the close contact processing agent.

### Example 1-6

The same evaluations as those for Example 1-1 were conducted, except that KB4403 was employed as the close contact processing agent.

### Example 1-7

The same evaluations as those for Example 1-1 were conducted, except that KBE585 was employed as the close contact processing agent.

### Example 1-8

The same evaluations as those for Example 1-1 were conducted, except that KBM803 was employed as the close contact processing agent.

### Comparative Example 1

HMDS was employed as the close contact processing agent, and a close contact process was administered on the surface of a Si substrate having a (50 nm) thermally oxidized film thereon, by a vapor process at 150° C. for 1 minute.

Thereafter, formation of the resist pattern and the evaluation of the pattern collapse suppressing effect were performed in the same manner as those for Example 1-1.

### (Evaluation Results)

The evaluation results for Examples 1-1 through 1-8 and Comparative Example 1 are shown in Table 3 below.

TABLE 3

| Close Contact | | | KBE- [symbol] 103 | Z8094 | Z8028 | KBM-973 | KBE-9007 | KBE-403 | KBE-585 | KBM-803 |
|---|---|---|---|---|---|---|---|---|---|---|
| Processing Agent | | HMDS | 0.1 wt % | 0.1 wt % | 0.1 wt % | 0.1 wt % | 0.1 wt % | 0.1 wt % | 0.1 wt % | 0.1 wt % |
| Functional Group | | Methyl Group | Amino Group | | | | Isocyanate | Epoxy | Unido Group | Mercapto |
| | | | | | | | Group | Group | | Group |
| AR | 1 | ◯ | ◯ | ◯ | ◯ | ◯ | ◯ | ◯ | ◯ | ◯ |
| | 1.2 | ◯ | ◯ | ◯ | ◯ | ◯ | X | X | ◯ | X |
| | 1.5 | X | ◯ | ◯ | ◯ | ◯ | X | X | X | X |
| | 1.6 | X | ◯ | ◯ | ◯ | ◯ | X | X | X | X |
| | 1.8 | X | ◯ | ◯ | ◯ | ◯ | X | X | X | X |
| | 2 | X | X | X | X | X | X | X | X | X |
| | 2.2 | X | X | X | X | X | X | X | X | X |
| | 2.4 | X | X | X | X | X | X | X | X | X |
| | 2.6 | X | X | X | X | X | X | X | X | X |
| | 3 | X | X | X | X | X | X | X | X | X |
| | 3.3 | X | X | X | X | X | X | X | X | X |

[symbol]

indicates data missing or illegible when filed

Pattern collapses were not confirmed through an aspect ratio of 1.2 in Comparative Example 1, but pattern collapses were found at aspect ratios of 1.5 and greater.

Pattern collapses were not confirmed through an aspect ratio of 1.8 in Examples 1-1 through 1-4, but pattern collapses were found at aspect ratios of 2.0 and greater. In Examples 1-5 through 1-8, pattern collapses were found at aspect ratios equivalent to or less than those in which pattern collapses were found for Comparative Example 1.

From the above, it was understood that pattern collapses can be suppressed more than had been conventionally possible in cases that amino series silane coupling agents were employed as close contact processing agents.

### Example 2

### Evaluation of Dependency on Concentration of Close Contact Processing Agents in Achieving Pattern Collapse Suppressing Effects

The concentration of the close contact processing agent in the diluted solution was changed for each of the resist compositions shown in Table 1, and evaluations regarding whether a pattern collapse suppressing effect was exhibited were performed. In addition, the thickness of residual film was measured for each concentration of the diluted solution. Further, pattern formability of substrates following processing of the substrates by RIE (Reactive Ion Etching) was evaluated. Z6094 was utilized as the close contact processing agent.

The evaluations regarding whether a pattern collapse suppressing effect was exhibited, measurement of the residual film thickness, and evaluations of the pattern formability of the substrates were performed as follows.

### Example 2-1

First, Z6094 was employed as a close contact processing agent, and a diluted solution was prepared by diluting the Z6094 to 0.01 wt % in PGME. Then, a close contact process was executed on a (50 nm) thermally oxidized film on the surface of a Si substrate using the diluted solution in the same manner as in Example 1-1.

Next, each of the resist compositions shown in Table 1 was utilized to produce resist patterns in the same manner as those of Example 1-1. Then, evaluations regarding whether a pattern collapse suppressing effect was exhibited were performed in the same manner as that for Example 1-1.

The residual film thicknesses was measured using a cross sectional SEM (Scanning Electron Microscope) in combination with a cross sectional TEM (Transmissive Electron Microscope) when necessary to confirm the cross sectional shape of the resist patterns, and to measure the thickness of the residual film present in the recesses of the resist pattern.

Further, the thermally oxidized films of Si substrates having resist films formed by resist compositions 1, 18, and 39 of Table 1 formed thereon were etched by RIE using the patterned resist films as masks after the residual films were removed with a target pattern height of 50 nm. Thereby, patterns of protrusions and recesses corresponding to the patterns of protrusions and recesses formed on the resist film were formed on the Si substrates, to obtain Si substrates having predetermined patterns thereon. Note that the substrate processing step was performed for resist patterns having aspect ratio so 1.2, 1.8, and 2.4. Resist compositions 1, 18, and 39 are those among the resist compositions 1 through 39 of Table 1 in which pattern collapse did not occur at all. The surface shapes of the patterned Si substrates obtained in the manner described above were observed by a cross sectional SEM (Scanning Electron Microscope) in combination with a cross sectional TEM (Transmissive Electron Microscope) when necessary to evaluate the pattern formability thereof.

The pattern formability was evaluated as “∘ (Good)” in the case that the average depth following RIE was 46 nm or greater and the fluctuation (c) in the depths was 3 nm or less, and evaluated as “x (poor)” in all other cases. Note that pattern formability was evaluated as “− (Collapse)” as excluded from evaluation, in cases that an evaluation of “∘ (Good)” was not obtained in the evaluation of pattern collapse suppressing effect, even if the pattern formability was favorable.

### Example 2-2

Evaluations were performed in the same manner as that for Example 2-1, except that the concentration of Z6094 was 0.03 wt %

### Example 2-3

Evaluations were performed in the same manner as that for Example 2-1, except that the concentration of Z6094 was 0.05 wt %

### Example 2-4

Evaluations were performed in the same manner as that for Example 2-1, except that the concentration of Z6094 was 0.08 wt %

### Example 2-5

Evaluations were performed in the same manner as that for Example 2-1, except that the concentration of Z6094 was 0.1 wt %

### Example 2-6

Evaluations were performed in the same manner as that for Example 2-1, except that the concentration of Z6094 was 0.25 wt %

### Example 2-7

Evaluations were performed in the same manner as that for Example 2-1, except that the concentration of Z6094 was 0.5 wt %

### Example 2-8

Evaluations were performed in the same manner as that for Example 2-1, except that the concentration of Z6094 was 1.0 wt %

### Example 2-9

Evaluations were performed in the same manner as that for Example 2-1, except that the concentration of Z6094 was 2.0 wt %

### Example 2-10

Evaluations were performed in the same manner as that for Example 2-1, except that the concentration of Z6094 was 3.0 wt %

### Example 2-11

Evaluations were performed in the same manner as that for Example 2-1, except that the concentration of Z6094 was 4.0 wt %

### Example 2-12

Evaluations were performed in the same manner as that for Example 2-1, except that the concentration of Z6094 was 5.0 wt %

### Comparable Example 2

HMDS was employed as the close contact processing agent. The results of Comparative Example 1 are applied with respect to formation of resist patterns and considerations regarding the pattern collapse suppressing effect.

Resist patterns were formed utilizing the resist compositions shown in Table 1 in the same manner as that for Example 1-1, to produce the same resist patterns as those of Example 1-1.

The residual film thicknesses of the resist films having resist patterns formed thereon in the manner described above were measured in the same manner as that for Example 2-1.

Further, the Si substrates having the resist films formed thereon as described above were processed in the same manner as that for Example 2-1, to obtain Si substrates having predetermined patterns thereon. The surface shapes of the patterned Si substrates obtained in the manner described above were observed by a cross sectional SEM (Scanning Electron Microscope) in combination with a cross sectional TEM (Transmissive Electron Microscope) when necessary to evaluate the pattern formability thereof.

The results of evaluation for Examples 2-1 through 2-12 and Comparative Example 2 are shown in Table 4 below.

TABLE 4

| | | | Z [symbol] | | | | | | | | | | | |
|---|---|---|---|---|---|---|---|---|---|---|---|---|---|---|
| Close Contact | | | 0.01 wt % | | 0.06 | 0.08 | 0.1 | 0.25 | 0.6 | | | | | |
| Processing Agent | | HMDS | or less | 0.03 wt % | wt % | wt % | wt % | wt % | wt % | 1 wt % | 2 wt % | 3 wt % | 4 wt % | 5 wt % |
| AR | 1 | ◯ | ◯ | ◯ | ◯ | ◯ | ◯ | ◯ | ◯ | ◯ | ◯ | ◯ | ◯ | ◯ |
| | 1.2 | ◯ | X | X | ◯ | ◯ | ◯ | ◯ | ◯ | ◯ | ◯ | ◯ | ◯ | ◯ |
| | 1.5 | X | X | X | ◯ | ◯ | ◯ | ◯ | ◯ | ◯ | ◯ | ◯ | ◯ | ◯ |
| | 1.6 | X | X | X | ◯ | ◯ | ◯ | ◯ | ◯ | ◯ | ◯ | ◯ | ◯ | ◯ |
| | 1.8 | X | X | X | ◯ | ◯ | ◯ | ◯ | ◯ | ◯ | ◯ | ◯ | ◯ | ◯ |

| | | | | | | | | | | | | | |
|---|---|---|---|---|---|---|---|---|---|---|---|---|---|
| Residual Film | 0.5 nm | 0 nm | 0.5 nm | 1.0 nm | 1.5 nm | 2.2 nm | 2.3 nm | 3.0 nm | 4.0 nm | 5.3 nm | 6.0 nm | 6.8 nm | 7.5 nm |
| Thickness | or less | | or less | | | | | | | | | | |
| Pattern Collapse | — | X | X | ◯ | ◯ | ◯ | ◯ | ◯ | ◯ | ◯ | ◯ | ◯ | ◯ |
| Pattern | ◯ | — | — | ◯ | ◯ | ◯ | ◯ | ◯ | ◯ | X | X | X | X |
| Formability | | Collapse | Collapse | | | | | | | | | | |
| AR = 1.2 | | | | | | | | | | | | | |
| Pattern | — | — | — | ◯ | ◯ | ◯ | ◯ | ◯ | ◯ | ◯ | X | X | X |
| Formability | Collapse | Collapse | Collapse | | | | | | | | | | |
| AR = 1.8 | | | | | | | | | | | | | |
| Pattern | — | — | — | ◯ | ◯ | ◯ | ◯ | ◯ | ◯ | ◯ | ◯ | X | X |
| Formability | Collapse | Collapse | Collapse | | | | | | | | | | |
| AR = 2.4 | | | | | | | | | | | | | |

[symbol]

indicates data missing or illegible when filed

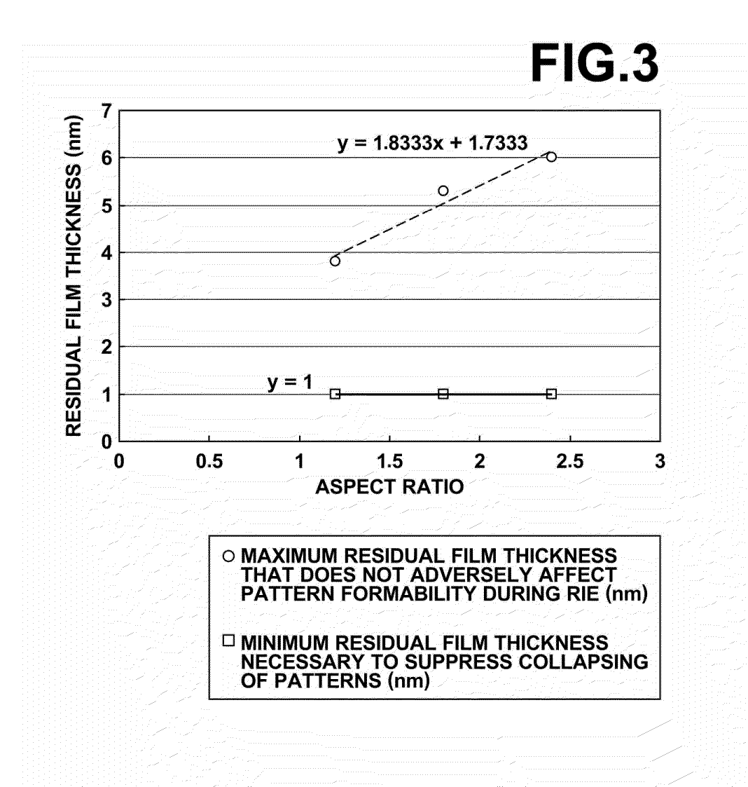

From the evaluation results shown in Table 4, it was under stood that it is possible to control the residual film thickness by changing the concentration of the close contact processing agent within the diluted solution. It was also understood that a residual film thickness of at least 1 nm is necessary in order to suppress collapsing of patterns in resist patterns having high aspect ratios. In addition, it was understood that although the pattern collapse suppressing effect is greater as the residual film is thicker, pattern formability of substrates following etching deteriorates if the residual film is excessively thick. Table 5 summarizes the lower limit value and the upper limit value of ranges of residual film thickness that enables the operative effects of the present invention to be obtained. FIG. 3 is a graph in which lower limit values and upper limit values of the ranges of the thickness of residual film are plotted, based on Table 5. From FIG. 3, it was understood that collapsing of patterns can be suppressed even in resist patterns having high aspect ratios if the thickness of residual films of resist films is 1 nm or greater and 1.83·AR+1.73 nm or less. Collapsing of patterns can be suppressed particularly in the case that the residual film thickness is within a range from 1 nm to 4 nm regardless of the aspect ratio of the resist pattern, and therefore it can be said that this range is preferable.

TABLE 5

| | Maximum Residual Film | Minimum Residual Film |
|---|---|---|
| | Thickness at which Pattern | Thickness Necessary to |
| | Formability following RIE | Suppress Collapsing of |
| | is not Adversely Affected | Patterns |
| AR | (nm) | (nm) |
| 1.2 | 3.8 | 1 |
| 1.8 | 5.3 | 1 |
| 2.4 | 6 | 1 |

What is claimed is:

1. A method for forming a resist pattern, comprising the steps of:
coating a substrate with a chemically amplified resist material;
exposing the resist material; and
developing the exposed resist material, to form a resist pattern having an aspect ratio AR of 1.5 or greater in a resist film formed by the resist material; wherein:
a close contact process that improves close contact properties between the substrate and the resist film is controlled such that the thickness of residual film of the resist film is greater than or equal to 1 nm and less than or equal to 1.83·AR+1.73 nm.

2. A method for forming a resist pattern as defined in claim 1, wherein:
an amino series silane coupling agent having an amino group is employed as a close contact processing agent in the close contact process; and
the close contact process is executed by coating the substrate with a diluted solution of the amino series silane coupling agent.

3. A method for forming a resist pattern as defined in claim 1, wherein:
the concentration of the amino series silane coupling agent within the diluted solution is controlled to control the close contact process.

4. A method for forming a resist pattern as defined in claim 2, wherein:
the concentration of the amino series silane coupling agent within the diluted solution is controlled to control the close contact process.

5. A method for forming a resist pattern as defined in claim 1, wherein:
the thickness of residual film is within a range from 1 nm to 4 nm.

6. A method for forming a resist pattern as defined in claim 2, wherein:
the thickness of residual film is within a range from 1 nm to 4 nm.

7. A method for forming a resist pattern as defined in claim 3, wherein:
the thickness of residual film is within a range from 1 nm to 4 nm.

8. A method for forming a resist pattern as defined in claim 4, wherein:
the thickness of residual film is within a range from 1 nm to 4 nm.

9. A method for processing a substrate, comprising:
forming a resist film having a predetermined resist pattern on a substrate by a method for forming a resist pattern as defined in claim 1;
removing the residual film of the resist film; and
etching the substrate using the resist film as a mask, to form a pattern of protrusions and recesses corresponding to the resist pattern on the substrate.
